(19) United States
(12) Patent Application Publication
(10) Pub. No.: US 2006/0232162 A1
(43) Pub. Date: Oct. 19, 2006

(54) Electrically driven mechanical actuators and methods of operating same

(75) Inventor: James Vogeley, Yorktown, VA (US)

Correspondence Address: NIXON & VANDERHYE, PC, 901 NORTH GLEBE ROAD, 11TH FLOOR, ARLINGTON, VA, 22203, US

(73) Assignee: PAR Technologies, LLC, Hampton, VA (US)

(21) Appl. No.: 11/104,667

(22) Filed: Apr. 13, 2005

(51) Int. Cl. H01L 41/09

(52) U.S. Cl. 310/317

(57) ABSTRACT

An electrically driven actuator (20, 120) comprises a deformable member (22, 122) which deforms as a function of applied voltage. A coupler (30) connects the deformable member to a shaft (40, 140) which, depending on embodiment and mode of operation, may be either displaceable along its axis or stationary. A controller (50, 150) actuates the deformable member by applying voltage in a manner to cause the coupler, as a function of applied voltage, either to engage or slip relative to the shaft, thereby causing relative displacement of the shaft and the deformable member. In one embodiment and mode of operation, the shaft (40) is displaceable and comprises an actuator element, whereas in another embodiment and mode of operation the deformable member (122) comprises the moveable actuator (121). Preferably, the controller actuates the deformable member to cause linear relative displacement of the shaft and the deformable member. In yet other embodiments and mode of operation, a deformable assembly (222) comprises a first deformable member (222A) and a second deformable member (222B), with the first deformable member (222A) being connected to a shaft (240) through a coupler (230) and the second deformable member (222B) being connected to a sleeve (270) which fits over the shaft (240) and allows relative translation of the shaft (240) and sleeve (270).

### BACKGROUND

1. Field of the Invention

The present invention pertains to electrically driven mechanical actuators.

2. Related Art and Other Considerations

Mechanical actuators are utilized in diverse and sundry environments and applications. Simple, inexpensive, and reliable mechanical actuators are highly beneficial and desirable.

### BRIEF SUMMARY

An electrically driven actuator comprises a deformable member which deforms as a function of applied voltage. A coupler connects the deformable member to a shaft which, depending on embodiment and mode of operation, may be either displaceable along its axis or stationary. A controller actuates the deformable member by applying voltage in a manner to cause the coupler, as a function of applied voltage, either to engage or slip relative to the shaft, thereby causing relative displacement of the shaft and the deformable member. In one embodiment and mode of operation, the shaft is displaceable and comprises an actuator element. In another embodiment and mode of operation the deformable member comprises the moveable actuator. Preferably, the controller actuates the deformable member to cause linear relative displacement of the shaft and the deformable member.

The controller applies a drive signal to the deformable member, the drive signal having a drive signal waveform. The coupler engages the shaft during an engagement portion of a cycle of the drive signal waveform but permits the slip of the coupler during a slip portion of the cycle of the drive signal waveform. In an illustrated example embodiment and mode of operation, the drive signal waveform causes relative displacement of the shaft and the deformable member in a first direction when the slip portion of the drive signal waveform precedes the engagement portion of the drive signal waveform, but in a second direction (opposite to the first direction) when the slip portion of the drive signal waveform follows the engagement portion of the drive signal waveform.

The drive signal waveform can have various shapes such as (for example) a half-sine waveform; a quarter-sine waveform; a sawtooth waveform; or even a hybrid waveform such as a partial quarter-sine, partial sawtooth waveform.

In an illustrated, example embodiment, the deformable member is a piezoelectric diaphragm, a piezoelectric polymer, or a voice coil, and the coupler is a friction coupler.

Methods of operating the actuator comprise connecting the shaft to the deformable member with a coupler (the deformable member being deformable as a function of voltage applied in a drive signal), and driving the deformable member with the drive signal in a manner to cause the coupler, as a function of applied voltage, either to engage or slip on the shaft and thereby cause relative displacement of the deformable member and the shaft.

One example embodiment of an electrically driven actuator comprises a piezoelectric diaphragm; a displaceable actuator element; and a coupler which connects the piezoelectric diaphragm to the actuator element. A controller actuates the piezoelectric diaphragm in a manner to cause the coupler, as a function of applied voltage, either to engage or slip on the actuator element and thereby displace the actuator element relative to the piezoelectric diaphragm. In an example implementation of this embodiment, the actuator element is a shaft having an axis, and the controller actuates the piezoelectric diaphragm to displace linearly the actuator element along the axis. In an example mode of operation, the piezoelectric diaphragm is driven in a manner to cause the coupler, as a function of applied voltage, either to engage or slip on the actuator element and thereby displace the actuator element relative to the piezoelectric diaphragm.

Another example embodiment of an electrically driven actuator comprises a displaceable actuator which includes a piezoelectric diaphragm; a guide element; and, a coupler which connects the piezoelectric diaphragm to the guide element. A controller actuates the piezoelectric diaphragm in a manner to cause the coupler, as a function of applied voltage, either to engage or slip on the guide element and thereby displace the actuator (which carries the piezoelectric diaphragm) relative to the guide element. In one example implementation of this embodiment, the guide element is a stationary shaft having an axis, and the controller actuates the piezoelectric diaphragm to displace linearly the actuator along the axis. In an example mode of operation, the piezoelectric diaphragm is driven in a manner to cause the coupler, as a function of applied voltage, either to engage or slip on the guide element and thereby displace the actuator relative to the guide element.

In yet another embodiment and mode of operation, a deformable assembly comprises a first deformable member and a second deformable member, with the first deformable member being connected to a shaft through a coupler and the second deformable member being connected to a stationary sleeve through which the shaft translates.

In yet another embodiment and mode of operation, a deformable assembly comprises a first deformable member and a second deformable member, with the first deformable member being connected to a shaft through a coupler and the second deformable member being connected to a translatable sleeve through which a stationary shaft extends.

### BRIEF DESCRIPTION OF THE DRAWINGS

The foregoing and other objects, features, and advantages of the invention will be apparent from the following more particular description of preferred embodiments as illustrated in the accompanying drawings in which reference characters refer to the same parts throughout the various views. The drawings are not necessarily to scale, emphasis instead being placed upon illustrating the principles of the invention.

FIG. 1 is a top view of electrically driven actuator according to a first example embodiment.

FIG. 2 is a sectioned side view of the actuator of FIG. 1 taken along the line 2-2.

FIG. 3A is a view showing a half sine wave drive voltage signal waveform.

FIG. 3B is a graph showing diaphragm velocity for the drive voltage signal waveform of FIG. 3A.

FIG. 3C is a graph showing diaphragm acceleration for the drive voltage signal waveform of FIG. 3A.

FIG. 3D is a graph showing actuator position for the drive voltage signal waveform of FIG. 3A.

FIG. 4A-FIG. 4B are sectioned diagrammatic side views showing operation of the actuator of FIG. 1 for displacing an actuator element in a first direction.

FIG. 5A-FIG. 5B are sectioned diagrammatic side views showing operation of the actuator of FIG. 1 for displacing an actuator element in a second direction.

FIG. 6 is a top view of electrically driven actuator according to a second example embodiment.

FIG. 7 is a sectioned side view of the actuator of FIG. 6 taken along the line 7-7.

FIG. 8A-FIG. 8B are sectioned diagrammatic side views showing operation of the actuator of FIG. 6 for displacing an actuator element in a first direction.

FIG. 9A-FIG. 9B are sectioned diagrammatic side views showing operation of the actuator of FIG. 6 for displacing an actuator element in a second direction.

FIG. 10A is a graphical view of two cycles of a half-sine waveform drive signal for displacing an actuator in a forward direction.

FIG. 10B is a graphical view of three cycles of a quarter-sine waveform drive signal for displacing an actuator in a forward direction.

FIG. 10C is a graphical view of three cycles of a sawtooth waveform drive signal for displacing an actuator in a forward direction.

FIG. 10D is a graphical view of three cycles of a quarter-sine waveform drive signal for displacing an actuator in a reverse direction.

FIG. 10E is a graphical view of three cycles of a partial quarter-sine, partial sawtooth waveform drive signal for displacing an actuator in a forward direction.

FIG. 11 is a top view of electrically driven actuator according to a third example embodiment.

FIG. 12 is a sectioned side view of the actuator of FIG. 11 taken along the line 12-12.

FIG. 13A-FIG. 13B are sectioned diagrammatic side views showing operation of the actuator of FIG. 11 for displacing an actuator element in a first direction.

FIG. 14 is a top view of electrically driven actuator according to a fourth example embodiment.

FIG. 15 is a sectioned side view of the actuator of FIG. 14 taken along the line 15-15.

FIG. 16A-FIG. 16B are sectioned diagrammatic side views showing operation of the actuator of FIG. 14 for displacing an actuator element in a first direction.

### DETAILED DESCRIPTION

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. In other instances, detailed descriptions of well-known devices, circuits, and methods are omitted so as not to obscure the description of the present invention with unnecessary detail.

### FIRST EMBODIMENT/MODE

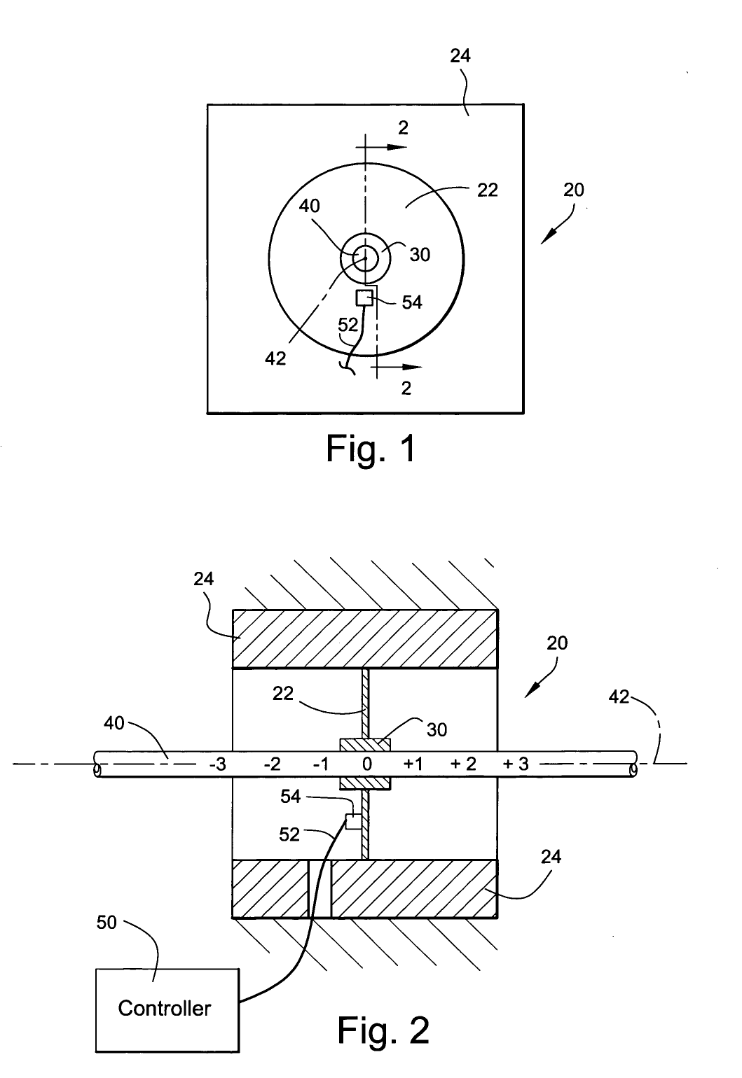

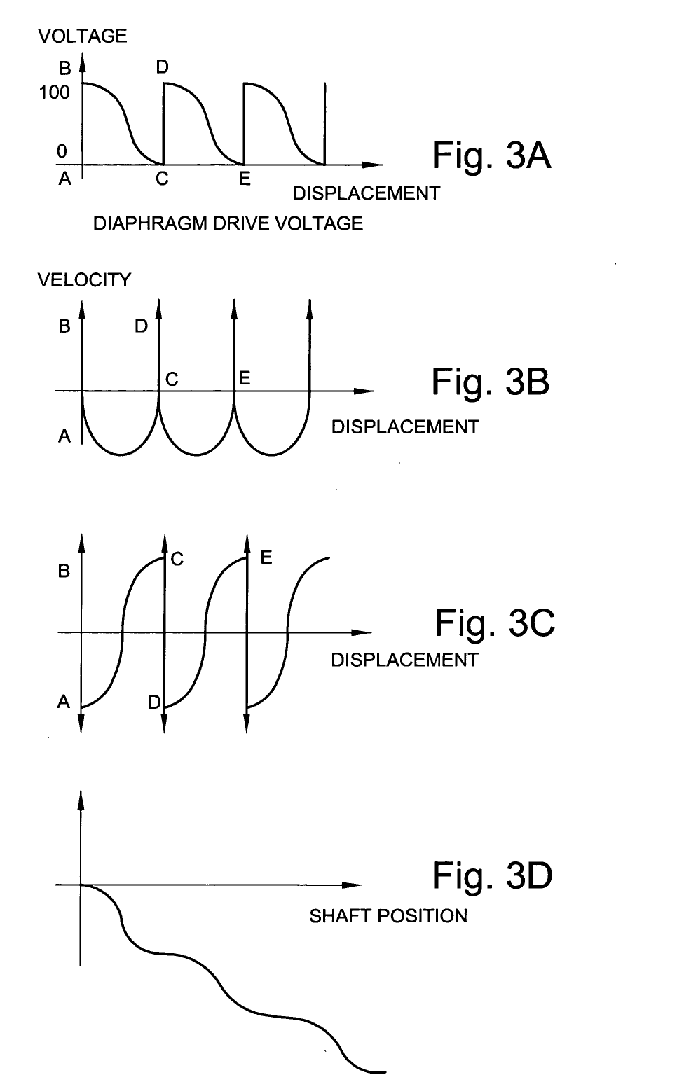

FIG. 1 and FIG. 2 show an electrically driven actuator 20 according to a first example embodiment. The actuator 20 comprises a deformable element or member 22 which is substantially flat (planar) or only slightly domed at rest (when an electrical signal having a first value (e.g., zero volts) is applied), but which deforms to have a greater degree of curvature as a function (when the electrical signal has a second value, e.g., a voltage greater than zero volts). As used herein, “relatively flat” includes diaphragms which have a slightly domed configuration when at rest (e.g., when unactivated).

In the example shown in FIG. 1 and FIG. 2, the deformable member 22 has a circular shape and is secured about its circumference in a stationary housing 24. For example, the periphery of deformable member 22 can be clamped by or otherwise held by or within stationary housing 24. The stationary housing 24 can have any desired shape as seen from above, e.g., a quadrilateral shape as shown in FIG. 2 or even a circular shape. Preferably but not necessarily the deformable member 22 is at the center of stationary housing 24.

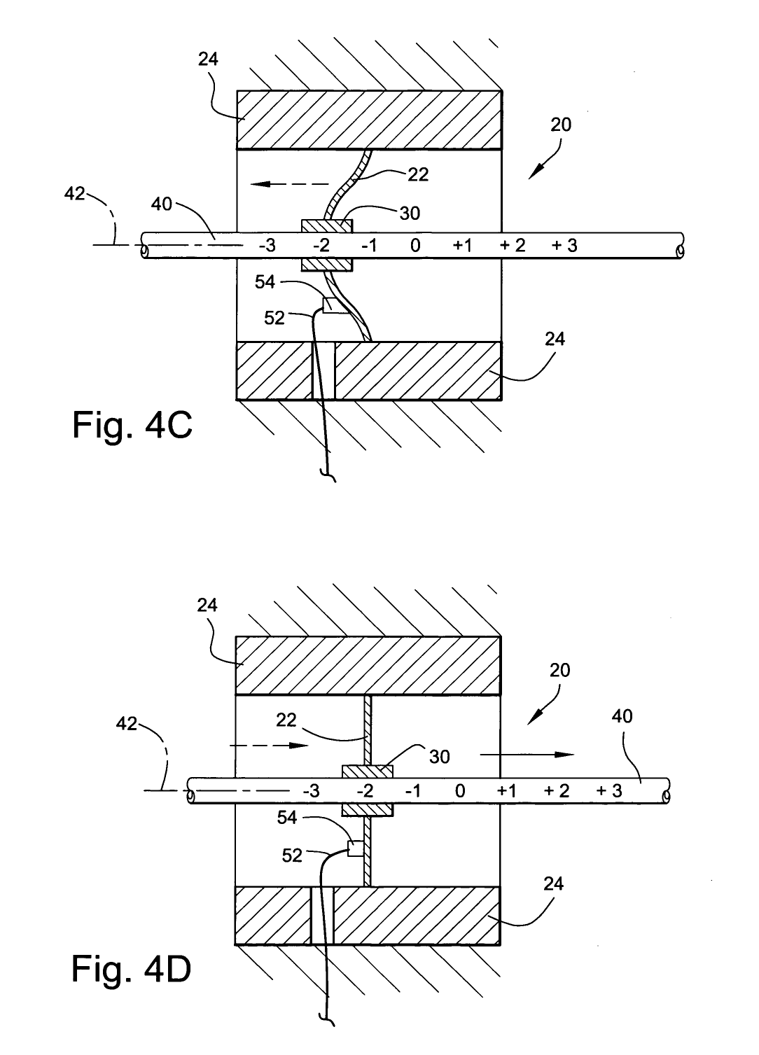

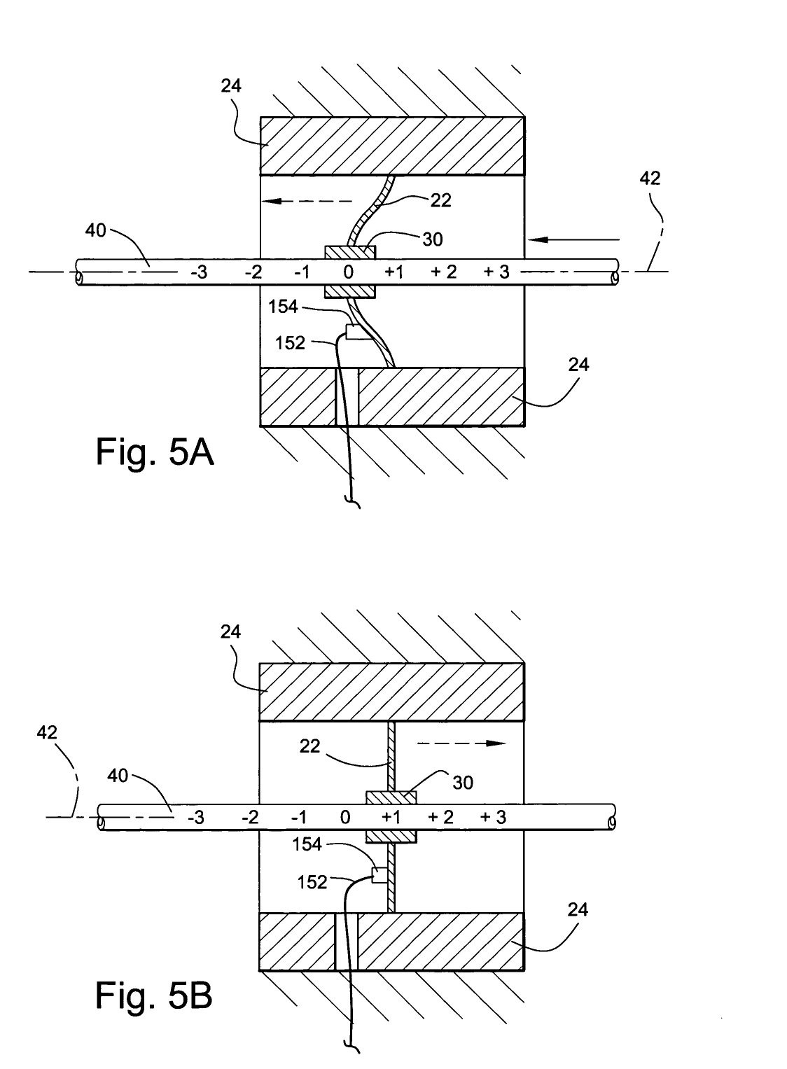

A coupler 30 connects the deformable member 22 to a shaft 40. The coupler 30 is preferably formed, fastened, or securely fitted through a hole at the center of deformable member 22. In the first embodiment or mode, shaft 40 is displaceable along its axis 42, as explained with reference to FIG. 4A-FIG. 4D and FIG. 5A-FIG. 5D. As explained subsequently, the coupler 30 is preferably a friction coupler.

A controller 50 actuates the deformable member 22 by applying voltage in a manner to cause coupler 30 either, as a function of applied voltage, to engage or slip relative to shaft 40, thereby causing relative displacement of shaft 40 and deformable member 22. The controller 50 connects by one or more signal lead 52 to one or more electrodes 54, or other drive structure(s), mounted on or operatively situated relative to deformable member 22.

In the particular embodiment and mode of operation shown in FIG. 1 and FIG. 2, shaft 40 is displaceable and comprises an actuator element. That is, shaft 40 itself may be a working member or may be connected to or otherwise linked or associated with a working member to cause displacement or other operation of an actuated device. In an example implementation of this embodiment, the deformable member is a piezoelectric diaphragm which is connected to the actuator element (e.g., shaft 40) by coupler 30. In this implementation, as explained below, controller 50 actuates the piezoelectric diaphragm 22 in a manner to cause the coupler 30, as a function of applied voltage, either to engage or slip on the actuator element (shaft 40) and thereby displace the actuator element (shaft 40) relative to the piezoelectric diaphragm 22.

FIG. 2 shows that, in an example implementation of the first embodiment, the shaft 40, being the actuator element, extends along an axis 42. Merely for sake of illustrating displacement of shaft 40, FIG. 2 (and certain other illustrations) show shaft 40 as having equally spaced graduation or measurement marks represented by numbers. A center or reference position of shaft 40 bears the mark or number 0, while in a first direction (shown to the right of reference mark 0) the monotonically increasing and equidistant integer numbers or marks +1, +2, +3, etc., are provided. In a second direction (shown to the left of reference mark 0) are the monotonically decreasing and equidistant integer numbers or marks −1, −2, −3, etc.

As explained hereinafter, controller 50 applies a drive signal to deformable member 22, e.g., via electrode 54 to the piezoelectric diaphragm in the illustrated implementation. The drive signal applied by controller 50 to deformable member 22 has a waveform, known herein as the drive signal waveform. As subsequently described, depending on various factors the drive signal waveform can be configured to have any of several desired shapes or configurations.

FIG. 4A-FIG. 4D illustrate modes of operation of the embodiment of FIG. 1 for displacing the actuator (e.g., shaft 40) in a first (forward) direction. In FIG. 4A-FIG. 4D, the forward direction is to the right. For sake of discussion, it is assumed that the example piezoelectric diaphragm 22 of FIG. 1 is used as a short stroke actuator. It is further assumed, for simplicity, that the piezoelectric diaphragm 22 is a “perfect” device, meaning that the piezoelectric diaphragm has zero impedance, has infinite frequency response, has infinite force, and is linear, etc. Yet further, it is assumed that the electronic drive provided by controller 50 is also “perfect” in that it is a zero impedance source with infinite frequency response. Thus, for sake of simplicity, the diaphragm/drive model of FIG. 1 is a pure displacement vs. voltage device such that x volts applied by controller 50 yields a diaphragm displacement of x distance units. In other words, the center of the ideal diaphragm is at axial position 0 at 0 volts, at axial position 1 at 1 volt, at axial position 2 at 2 volts, etc. In actual example implementations, on the other hand, other correlations between applied voltage and position or displacement may be established. For example, in one embodiment a 0.002 inch displacement results for a 400 volt excitation signal applied by controller 50.

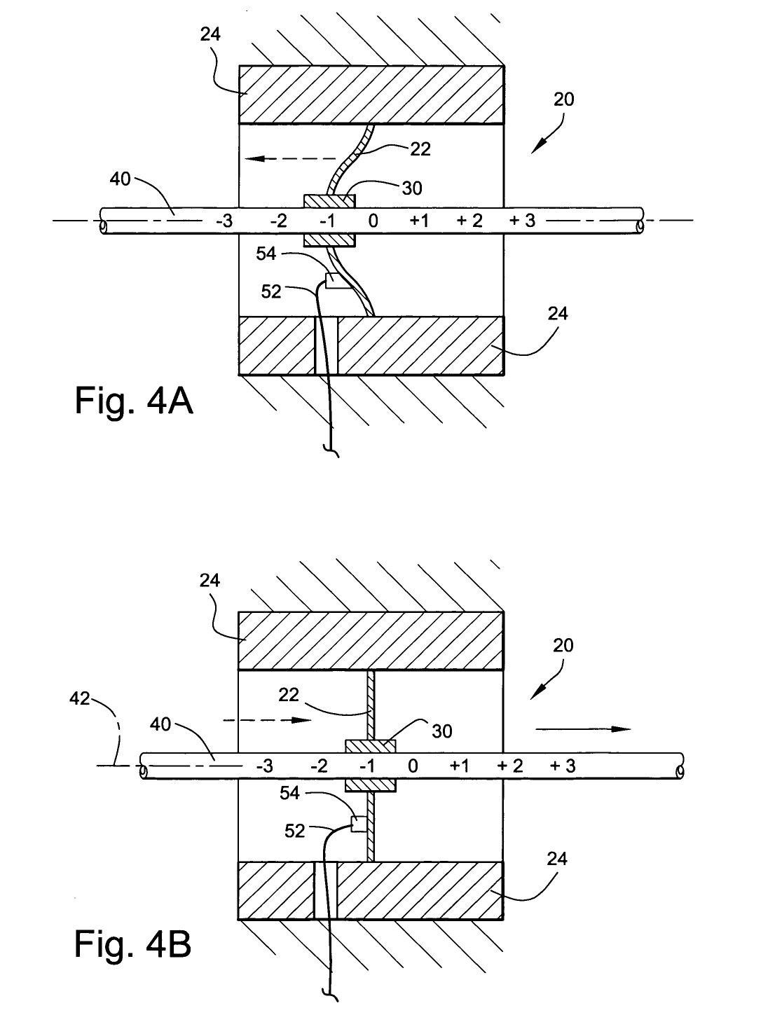

As explained above, in FIG. 1 and FIG. 2 the piezoelectric diaphragm 22 is attached to a mass (e.g., the actuator element 40) by a friction connection or coupler 30. The timing diagram of FIG. 3A shows controller 50 applying a half-sine waveform drive signal to the electronic drive of the piezoelectric diaphragm. The drive signal waveform is applied on signal lead 52 to electrode 54, which activates the piezoelectric diaphragm 22. At point A of FIG. 3A, the piezoelectric diaphragm 22 is at position 0, which corresponds to piezoelectric diaphragm 22 being at mark 0 of shaft 40 as shown in FIG. 2. Then, at point B of FIG. 3A, reached an “infinitely short” period of time later, the piezoelectric diaphragm 22 is at position 100 in FIG. 3A, which corresponds to mark −1 of shaft 40 as shown in FIG. 4A. To move in “zero” time from position 0 to position 100 (of FIG. 3A), and thus from shaft mark 0 to shaft mark −1 of FIG. 4B, the piezoelectric diaphragm 22 must accelerate at an “infinite” rate. The movement of piezoelectric diaphragm 22 is depicted herein by broken arrows, with the broken arrow pointing left (as shown in FIG. 4A) indicating deformation of piezoelectric diaphragm 22 and the broken arrow pointing right indicating that the piezoelectric diaphragm 22 regains its inactivated or relatively flat orientation. The force presented to the friction coupler 30 during this time equals the mass of shaft 40 times the acceleration of the piezoelectric diaphragm (f=ma), where m is infinity. This “infinite” force overcomes the coefficient of friction so that the friction coupler 30 “slips” on shaft 40 to a new axial location x+100 (see FIG. 3A and FIG. 4A). Just like the old magic trick where a table cloth is yanked out from under all of the place settings of a dinner table, during the “slip” the shaft 40 (like the dishes) remains at rest.

Next consider in FIG. 3A the motion from time B to time C, in which the piezoelectric diaphragm 22 moves in the opposite direction (in the direction of the broken arrow of FIG. 4B). The position of the piezoelectric diaphragm 22 at any point in time is directly related to the applied voltage. The velocity of the piezoelectric diaphragm is directly related to the derivative of applied voltage, as shown in FIG. 3B. The acceleration of the piezoelectric diaphragm is the second derivative or −sin(x), as shown in FIG. 3C. For design convenience, a period for −sin(x) is chosen such that the force applied to the friction coupler 30 stays substantially below the force required to overcome the coefficient of friction and thus on this part of the cycle, the shaft remains “attached” or “engaged” to the piezoelectric diaphragm 22 and the two move and accelerate and decelerate together. The broken arrow in FIG. 4B shows the direction of movement, the direction of the solid arrow of FIG. 4B (and other drawings herein) shows the direction of movement of the shaft 40. The shaft 40 has “jumped” to a new discrete position relative to the piezoelectric diaphragm 22, and the two are now moving back to the origin of the piezoelectric diaphragm (i.e., the planar configuration of piezoelectric diaphragm 22) so that the cycle may be repeated (FIG. 4B). As a result of such “jumping” or moving, shaft 40 has been displaced one unit (e.g., from mark 0 to mark −1) in the forward direction (one unit to the right in FIG. 4B).

By repeating the cycle over and over, the shaft 40 can be moved or displaced more units in the forward direction. For example, by applying another cycle of the drive signal, the shaft 40 can be moved one more unit forward so that the piezoelectric diaphragm is aligned with mark −2 of shaft 40. In this regard, transition from point C to point D in FIG. 3A is reflected in FIG. 4C by deflection of the piezoelectric diaphragm 22 to shaft mark −2 as the coupler 30 slips along shaft 40 in the reverse direction depicted by the broken arrow. Then, from point D to point E of FIG. 3A, the piezoelectric diaphragm 22 moves in the forward direction, with coupler 30 engaging shaft 40 and moving shaft 40 forward (in the direction of the solid arrow) by one unit. Thus, at the end of the second cycle of FIG. 3A, the shaft 40 has moved two units, e.g., mark −2 of shaft 40 is now at the center or zero position of the relatively flat piezoelectric diaphragm 22.

Thus, coupler 30 engages the shaft 40 during an engagement portion of a cycle of the drive signal waveform but permits the slip of the coupler during a slip portion of the cycle of the drive signal waveform. With reference to the operation described in FIG. 4A-FIG. 4D, the drive signal waveform causes relative displacement of the shaft and the deformable member in a first (or forward) direction when the slip portion of the drive signal waveform precedes the engagement portion of the drive signal waveform. Conversely, as explained below with reference to FIG. 5A-FIG. 5D, the drive signal waveform causes relative displacement of the shaft and the deformable member in a second or reverse direction (opposite to the first direction) when the slip portion of the drive signal waveform follows the engagement portion of the drive signal waveform.

In considering reverse direction movement of shaft 40 as described in FIG. 5A-FIG. 5D, assume again that the piezoelectric diaphragm 22 and shaft 40 are initially positioned as shown in FIG. 2, with mark 0 of shaft 40 being aligned with piezoelectric diaphragm 22 when piezoelectric diaphragm 22 is in its unactivated (relatively flat) configuration. Then, if the waveform of FIG. 3A is reversed such that the sine or displacement portion leads the slip portion, during the deflection of piezoelectric diaphragm 22 in the reverse direction (depicted by the broken arrow in FIG. 5A) the coupler 30 engages shaft 40 and also moves shaft 40 in the reverse direction (the direction of movement of shaft 40 being illustrated by the solid arrow). So shaft 40 is displaced one unit rearwardly as shown in FIG. 5A. Then, during the slip portion of the drive signal waveform, the piezoelectric diaphragm 22 moves back to the right, with coupler 30 slipping over shaft 40. As a result, shaft 40 is situated with its reference mark 0 being one unit rearward of the neutral (unactivated) or relatively flat position of piezoelectric diaphragm 22 as shown in FIG. 5B. As such, shaft 40 has been displaced one unit in the reverse direction. Further displacement in the reverse direction can continue, as depicted in FIG. 5C and FIG. 5D which illustrate displacement by one more unit in the reverse direction.

### SECOND EMBODIMENT/MODE

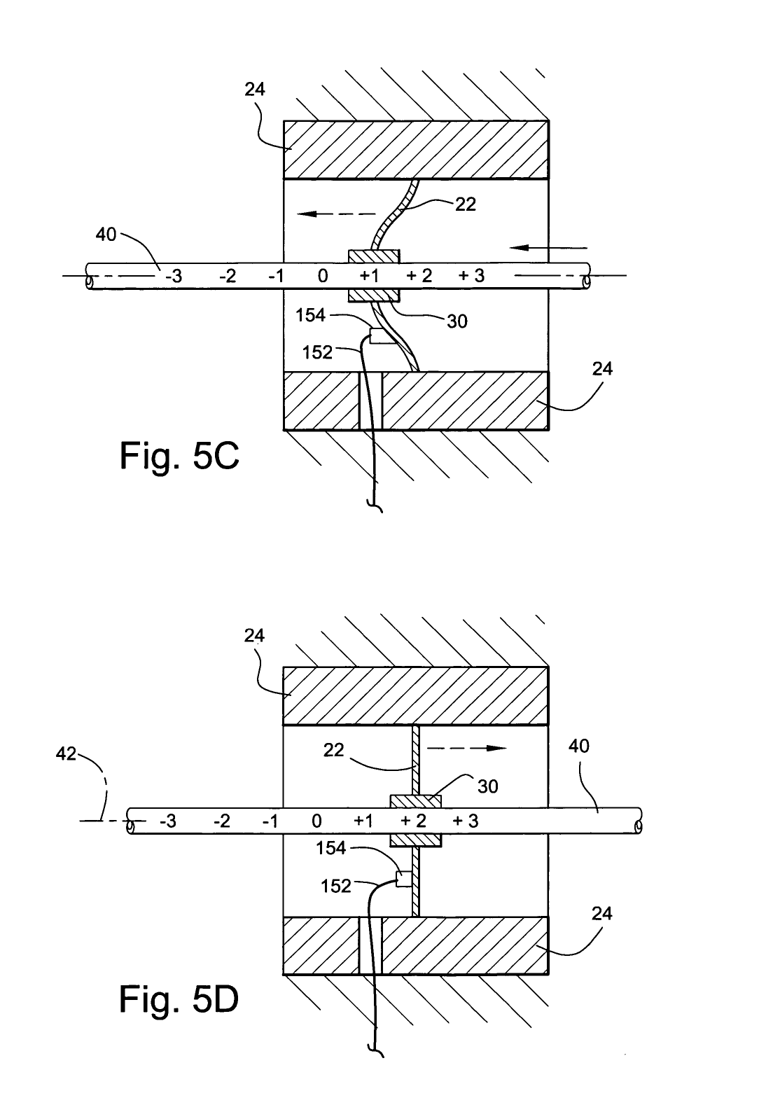

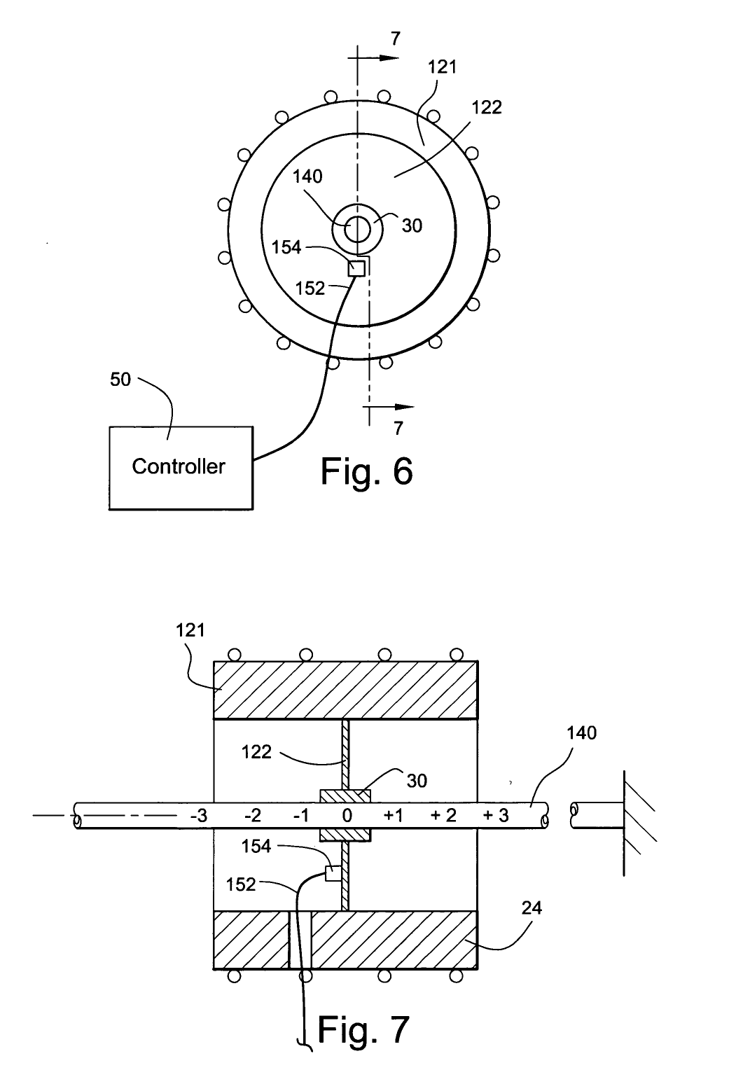

FIG. 6 and FIG. 7 illustrate another example embodiment of an electrically driven actuator, i.e., actuator 120. Actuator 120 comprises a displaceable actuator carriage 121 which includes piezoelectric diaphragm 122. To depict that carriage 121 is moveable, rollers or bearings 124 are shown about the periphery of carriage 121. It should be understood that such rollers or bearings 124 are merely representative of mobility, and that actual mobility of carriage 121 relative to it environment may be accomplished by alternate arrangements or even be free-floating in space (supported, e.g., by the stationary shaft).

Carriage 121 may be a working member or may be connected to, carry, or otherwise linked or associated with a working member to cause displacement or other operation of an actuated device. A coupler 30, shown in FIG. 6 as being situated through a hole at the center of piezoelectric diaphragm 122, connects the piezoelectric diaphragm 122 to a stationary guide element 140. As in the previous embodiment, the coupler 30 is preferably a friction coupler. The stationary guide element 140 can take the form of a shaft or other suitable guideway or track. While guide element 140 is shown in FIG. 7 as being linear, the guide element 140 may be configured to form a non-linear track.

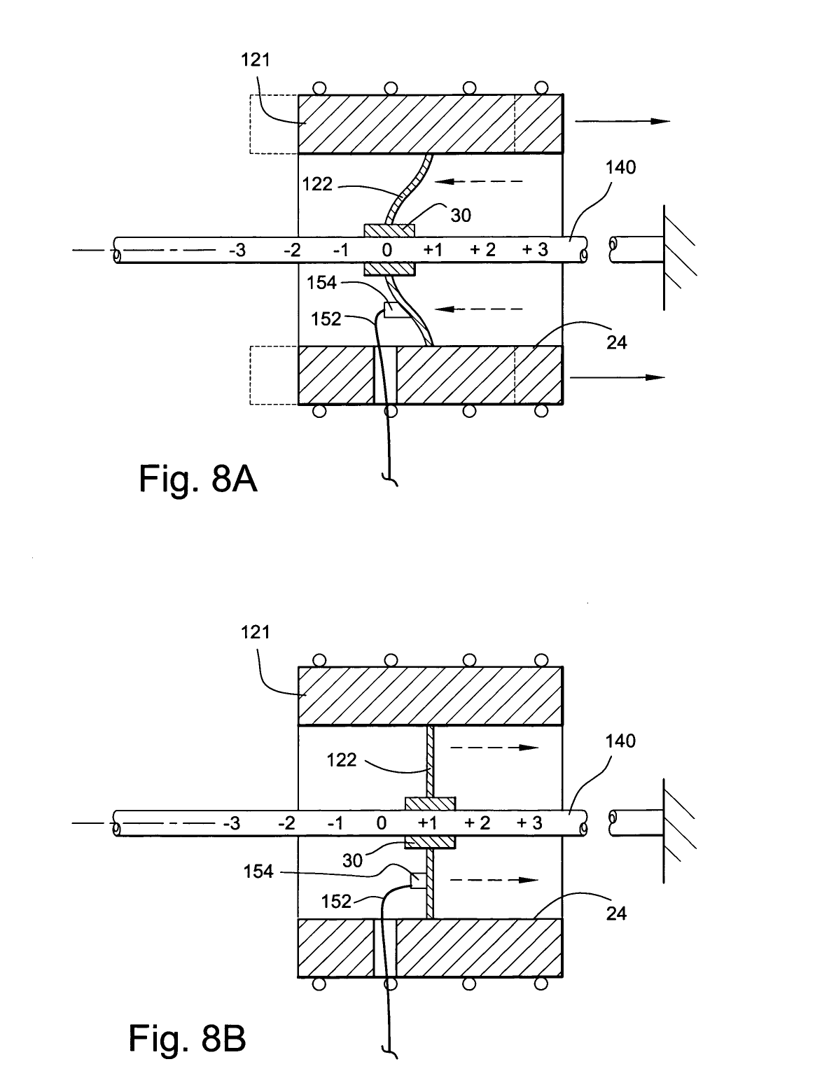

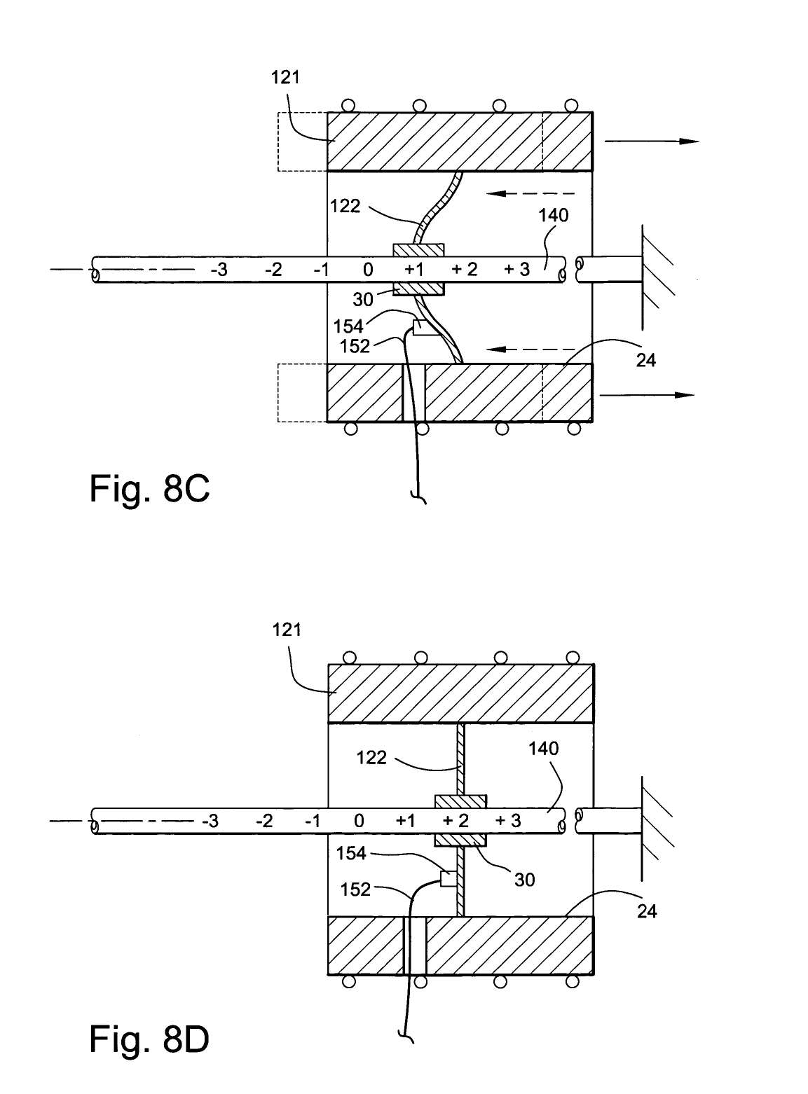

In the embodiment of FIG. 6 and FIG. 7, controller 150 actuates the piezoelectric diaphragm 122 in a manner to cause coupler 30, as a function of applied voltage, either to engage or slip on guide element 140, and thereby displace the actuator carriage 121 (which carries the piezoelectric diaphragm 122) relative to the guide element 140. In FIG. 7, as well as FIG. 8A-FIG. 8D and FIG. 9A-FIG. 9D, the stationary guide element 140 is shown with reference marks. In the second embodiment, the reference marks of guide element 140 are utilized to depict relative displacement of carriage 121 relative to the center or 0 reference mark of guide element 140. As in the previous illustrations, in FIG. 8A-FIG. 8D and FIG. 9A-FIG. 9D the direction of travel of the piezoelectric diaphragm 122 is depicted by the broken arrow. However, in FIG. 8A-FIG. 8D and FIG. 9A-FIG. 9D the direction of travel of the carriage 121 (now the actuator element) is shown by the solid arrow.

To the extent not inconsistent herewith, comments concerning the structural and operational details of the first embodiment also apply to the second embodiment. As a non-limiting example, the actuator 120 also has a controller 150 which supplies a drive signal via line 152 to electrode 154 or other application device. As in the first embodiment, coupler 30 engages the guide element 140 during an engagement portion of a cycle of the drive signal waveform but permits the slip of the coupler relative to guide element 140 during a slip portion of the cycle of the drive signal waveform.

FIG. 8A-FIG. 8D illustrate modes of operation of the embodiment of FIG. 6 and FIG. 7 for displacing the actuator in a first (forward) direction. For the second embodiment, the drive signal waveform causes relative displacement of carriage 121 and the deformable member carried thereby in a first (or forward) direction when the engagement portion of the drive signal waveform precedes the slip portion of the drive signal waveform.

FIG. 8A shows application of the engagement portion of a first cycle of the drive signal waveform after the time shown in FIG. 7. During the engagement portion the center of the deforming piezoelectric diaphragm 22 is, via coupler 30, rigidly affixed about guide element 140. Accordingly, the deformation of piezoelectric diaphragm 122 causes the carriage 121, which grasps or otherwise engages the periphery of piezoelectric diaphragm 122, to displace in the forward direction as shown by the solid arrows in FIG. 8A. For example, FIG. 8A shows the periphery of deformed piezoelectric diaphragm 122 to be displaced to mark +1 of guide element 140. The deformation of piezoelectric diaphragm 122 thus causes carriage 121 to displace from its former position centered at mark 0 (and depicted by dotted lines in FIG. 8A) to the new solid line carriage position now centered about mark +1.

During the ensuing slip portion of the drive signal waveform shown in FIG. 8B, the coupler 30 slips to the +1 mark position as the piezoelectric diaphragm 122 regains its relatively flat (inactivated) orientation. As such, the carriage 121 has been displaced one unit along guide element 140, with piezoelectric diaphragm 122 now in a relatively flat (inactivated) position and thus ready for another possible displacement. Further forward displacement of carriage 121 is indeed illustrated in FIG. 8C and FIG. 8D, which essentially repeat the engagement portion (FIG. 8C) and the slip portion (FIG. 8D) of the next cycle of the drive signal waveform, resulting in the carriage 121 moving another unit forward (so that the center of carriage 121 is now located at mark +2 of guide element 140).

Conversely, as illustrated by FIG. 9A-FIG. 9D, in the second embodiment the drive signal waveform causes relative displacement of carriage 121 and the deformable member carried thereby in a second (or reverse) direction when the slip portion of the drive signal waveform precedes the engagement portion of the drive signal waveform. In considering reverse direction movement of carriage 121 in conjunction with FIG. 9A-FIG. 9D, assume again that the carriage 121 and its piezoelectric diaphragm 122 are initially positioned as shown in FIG. 7, with the center of carriage 121 being aligned with mark 0 of guide element 140 when piezoelectric diaphragm 122 is in its unactivated (relatively flat) configuration. Then, if the slip portion of the waveform precedes the engagement portion of the waveform much in the manner of FIG. 3A, upon deformation of the piezoelectric diaphragm 122 the coupler 30 slips about guide element 140, with carriage 121 remaining still. As a result the coupler 30 and center of piezoelectric diaphragm 122 are displaced to mark −1 of guide element 140, while the periphery of piezoelectric diaphragm 122 and carriage 121 remain at mark 0 of guide element 140.

Following, during the engagement portion of the drive signal waveform as shown in FIG. 9B, the piezoelectric diaphragm 122 is inactivated to return to its relatively flat configuration, and in so doing thereby displaces the carriage 121. Upon completion of the flattening of piezoelectric diaphragm 122, the center of carriage 121 is now aligned at mark −1 of guide element 140. Thus, the carriage 121 has moved one unit in the reverse direction. The movement or displacement of carriage 121 is evident from the dotted line representation in FIG. 9B of the previous (FIG. 7) position of carriage 121.

The carriage 121 can be displaced further in the reverse direction by a further cycle of the drive signal waveform which has the engagement portion preceding the slip portion. Indeed, FIG. 9C and FIG. 9D show positions of the piezoelectric diaphragm 122 after such further cycle, resulting in the center of carriage 121 now being aligned at mark −2 of guide element 140. Thus, the carriage 121 has moved one more unit in the reverse direction. This further movement or displacement of carriage 121 is evident from the dotted line representation in FIG. 9D of the previous (FIG. 9C) position of carriage 121.

### THIRD EMBODIMENT/MODE

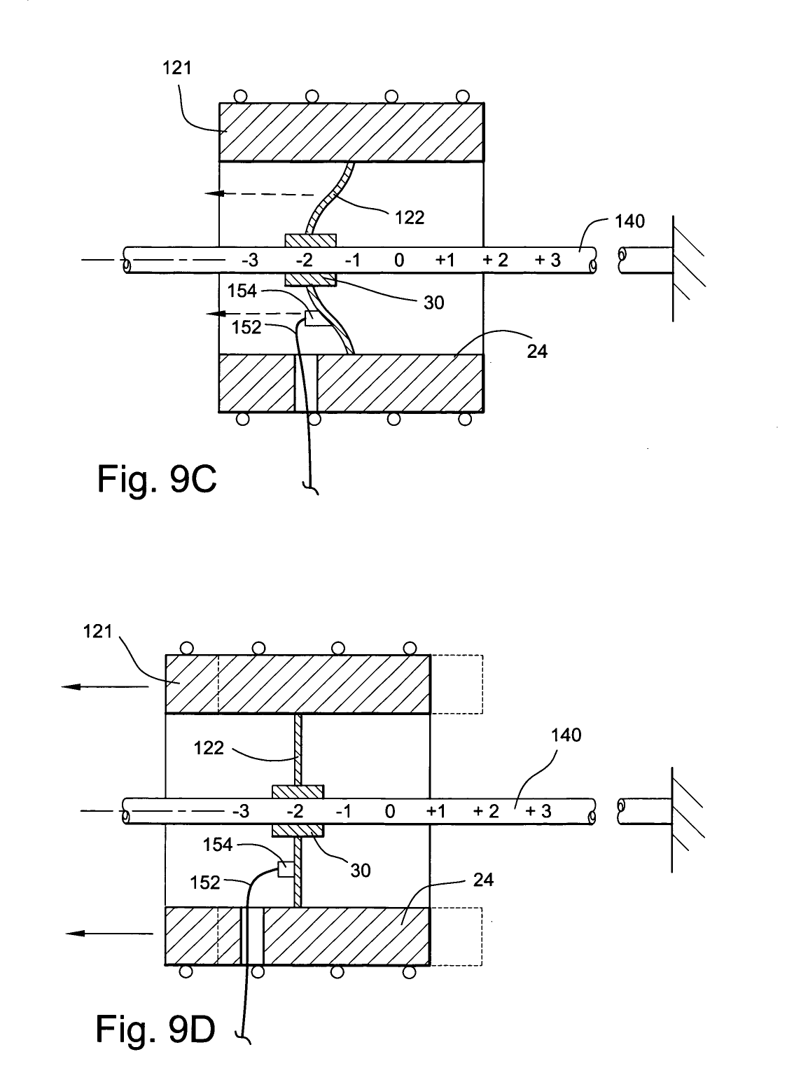

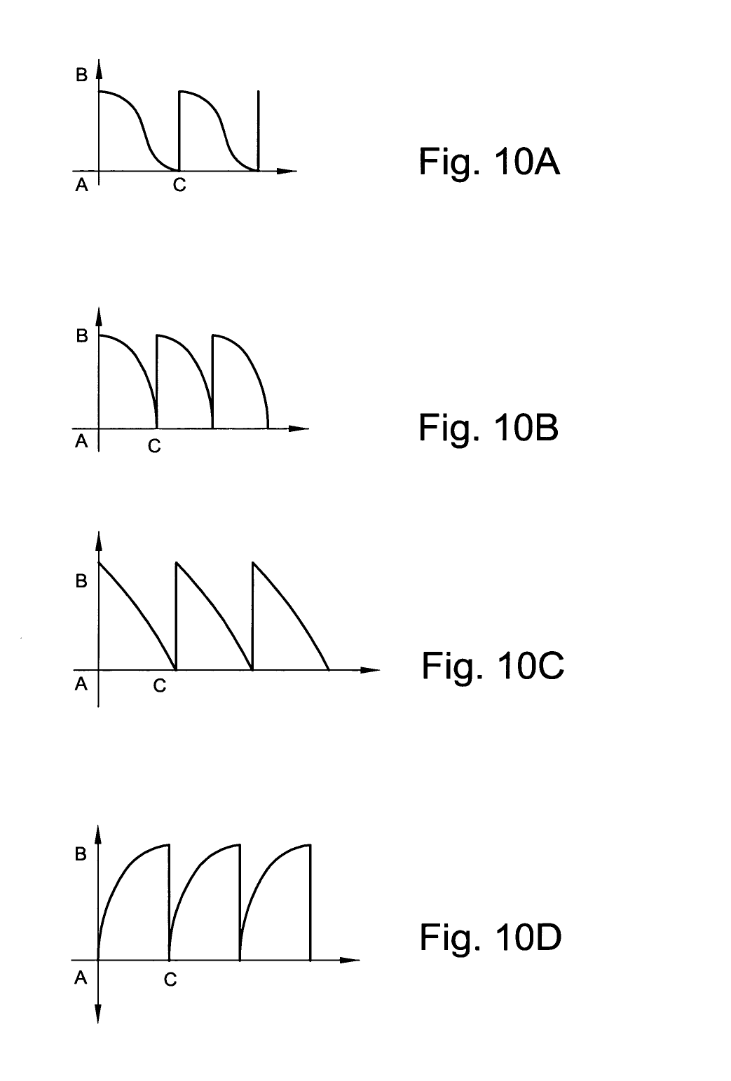

FIG. 11 and FIG. 12 illustrate another example embodiment of an electrically driven actuator, i.e., actuator 220. The actuator 20 comprises an assembly 222 of two deformable members, e.g., deformable members 222A and 222B. Both deformable members 222A and 222B are essentially circular in shape. However, unlike the previous embodiments, deformable members 222A and 222B comprising assembly 222 are not secured about their circumference to stationary housing 224. Rather, the peripheral edges of deformable members 222A and 222B are secured or bonded to one another, so that the assembly 222 essentially acquires the shape of an oyster or claim shell, e.g., a bellows configuration. As such, the peripheral edges of the deformable members 222A and 222B are not attached to, and do not contact, stationary housing 224.

In an example implementation of this embodiment, both deformable member 222A and deformable member 222B are piezoelectric diaphragms which have their peripheries bonded or otherwise connected together to form the bellows assembly 222. The bonding or securing of two piezoelectric diaphragms in this bellows arrangement is understood with reference to U.S. patent application Ser. No. 11/024,943, filed Dec. 30, 2004, entitled “PUMPS WITH DIAPHRAGMS BONDED AS BELLOWS”, which is incorporated herein by reference in its entirety.

As in preceding embodiments, stationary housing 224 can have any desired shape as seen from above, e.g., a quadrilateral shape or even a circular shape. Preferably but not necessarily the assembly 222 is at the center of stationary housing 224.

A first of the deformable members, i.e., deformable member 222A, is connected to a coupler 230. As in previous embodiments, coupler 230 connects the deformable member 222A to a shaft 240. The coupler 230 is preferably formed, fastened, or securely fitted through a hole at the center of deformable member 222A. In the third embodiment or mode, shaft 240 is displaceable along its axis 242. Preferably the coupler 230 is preferably a friction coupler.

A center of deformable member 222B has an aperture or hole which securely fits over a first axial end of shaft sleeve 270. The shaft sleeve 270 is ringed shaped, fitting concentrically over shaft 240, but having a sufficiently large interior radius so as not to contact shaft 240 (the shaft 240 being free to translate through the interior of shaft sleeve 270). Whereas the first axial end of shaft sleeve 270 is held in position by deformable member 222B (which itself is held by deformable member 222A and coupler 230), a second axial end of shaft sleeve 270 is held in position by brace(s) 274. The brace(s) 274 extend radially from the circumference of shaft sleeve 270 and are connected to fixed points on stationary housing 224. The brace(s) 274 hold the shaft sleeve 270 firmly in a fixed position so that shaft sleeve 270 does not travel relative to stationary housing 224. The brace(s) can take the form of a rigid ring positioned about the second axial end of shaft sleeve 270, or spokes, or even a pair of rigid beams, for example.

FIG. 12 shows the actuator 220 with the deformable member 222A and deformable member 222B being unactivated. When unactivated, the bellows configuration has its flattest (or narrowest) possible configuration, e.g., the deformable member 222A and deformable member 222B have their least degree of curvature. At the time shown in FIG. 12, the zero position of shaft 240 is essentially aligned with assembly 222. For sake of illustrating displacement of shaft 240, the shaft 240 is illustrated as having equally spaced graduation or measurement marks represented by numbers as in previous embodiments.

A controller 250 connects by one or more signal leads 252 to one or more electrodes, or other drive structure(s), mounted on or operatively situated relative to deformable member 222A and deformable member 222B. Controller 250 applies a drive signal to both deformable member 222A and deformable member 222B. The drive signal applied by controller 250 has a waveform, known herein as the drive signal waveform. As subsequently described, depending on various factors the drive signal waveform can be configured to have any of several desired shapes or configurations.

In applying the drive signal waveform, controller 250 can actuate deformable member 222A and deformable member 222B to cause deformable member 222A and deformable member 222B to deflect from their narrowest configuration to a fuller (or open) configuration. As the deformable member 222A changes its curvature (e.g., deforms), the coupler 23 attached thereto either engages or slips relative to shaft 240.

Thus, in the particular embodiment and mode of operation shown in FIG. 11 and FIG. 12, shaft 240 is displaceable and comprises an actuator element. That is, shaft 240 may be a working member or may be connected to or otherwise linked or associated with a working member to cause displacement or other operation of an actuated device.

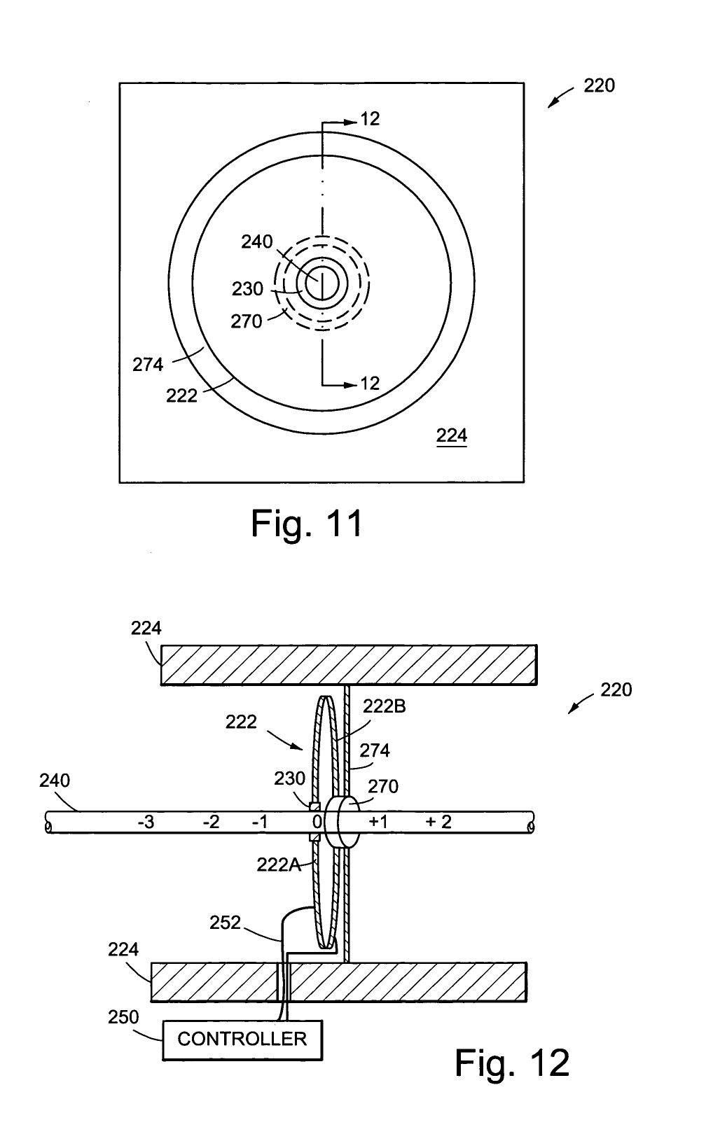

FIG. 13A-FIG. 13B illustrate modes of operation of the embodiment of FIG. 11 for displacing the actuator (e.g., shaft 240) in a first (forward) direction. In FIG. 13A-FIG. 13D, the forward direction is to the right. The assumptions concerning the first embodiment/mode generally apply to the third embodiment as well. For sake of illustration, the center of the deformable assembly 222 is at axial position 0 at 0 volts, and the timing diagrams of FIG. 3A-FIG. 3D are applicable. At point A of FIG. 3A, the deformable assembly 222 is at position 0. Then, at point B of FIG. 3A, reached an “infinitely short” period of time later, both deformable member 222A and deformable member 222B have been activated so that both deflect in the manner shown in FIG. 13A. In FIG. 13A, the deformable assembly 222 is at position 100 in FIG. 3A, which corresponds to mark −2 of shaft 40 as shown in FIG. 4A.

Next consider in FIG. 3A the motion from time B to time C, in which the deformable assembly 222 collapses (with its deformable member 222A and 222B returning to their smallest curvature orientations). The force applied to the friction coupler 230 stays substantially below the force required to overcome the coefficient of friction and thus on this part of the cycle, the shaft remains “attached” or “engaged” to the deformable assembly 222 and the two move and accelerate and decelerate together. In FIG. 13B, shaft 240 has “jumped” to a new discrete position relative to the deformable assembly 222, so that the shaft position −2 is now at the center of the deformable assembly 222. As a result of such “jumping” or moving, shaft 240 has been displaced two units in the forward direction (two units to the right in FIG. 13B).

As understood, e.g., with reference to the first embodiment, by repeating the cycle over and over, the shaft 240 can be moved or displaced more in the forward direction in multiples of two units. For example, by applying another cycle of the drive signal, the shaft 240 can be moved two more units forward so that the shaft mark −4 of shaft 240 is centered at deformable assembly 222.

Thus, coupler 230 engages the shaft 240 during an engagement portion of a cycle of the drive signal waveform but permits the slip of the coupler during a slip portion of the cycle of the drive signal waveform. With reference to the operation described in FIG. 13A-FIG. 13B, the drive signal waveform causes relative displacement of the shaft and the deformable member in a first (or forward) direction when the slip portion of the drive signal waveform precedes the engagement portion of the drive signal waveform. Conversely, as understood by analogy from the explanation of the first embodiment with reference to FIG. 5A-FIG. 5D, the drive signal waveform causes relative displacement of the shaft and the deformable assembly 222 in a second or reverse direction (opposite to the first direction) when the slip portion of the drive signal waveform follows the engagement portion of the drive signal waveform.

The third embodiment and mode of operation thus permits “jumping” or displacement at increments which are twice the size of the displacement increments of the first embodiment.

### FOURTH EMBODIMENT/MODE

The first embodiment/mode featured a moveable or translatable shaft 40 in conjunction with a single diaphragm 22, while the second embodiment/mode featured a moveable carriage 121 which translates as a single piezoelectric diaphragm 122 acts upon a stationary shaft 140. The third embodiment/mode featured a moveable or translatable shaft 240 in conjunction with a deformable bellows or oyster shell diaphragm assembly 222. By analogy to the second embodiment/mode and with respect to the third embodiment/mode, the fourth embodiment/mode features a moveable carriage 321 which translates as a deformable bellows diaphragm assembly 322 acts upon a stationary shaft 340.

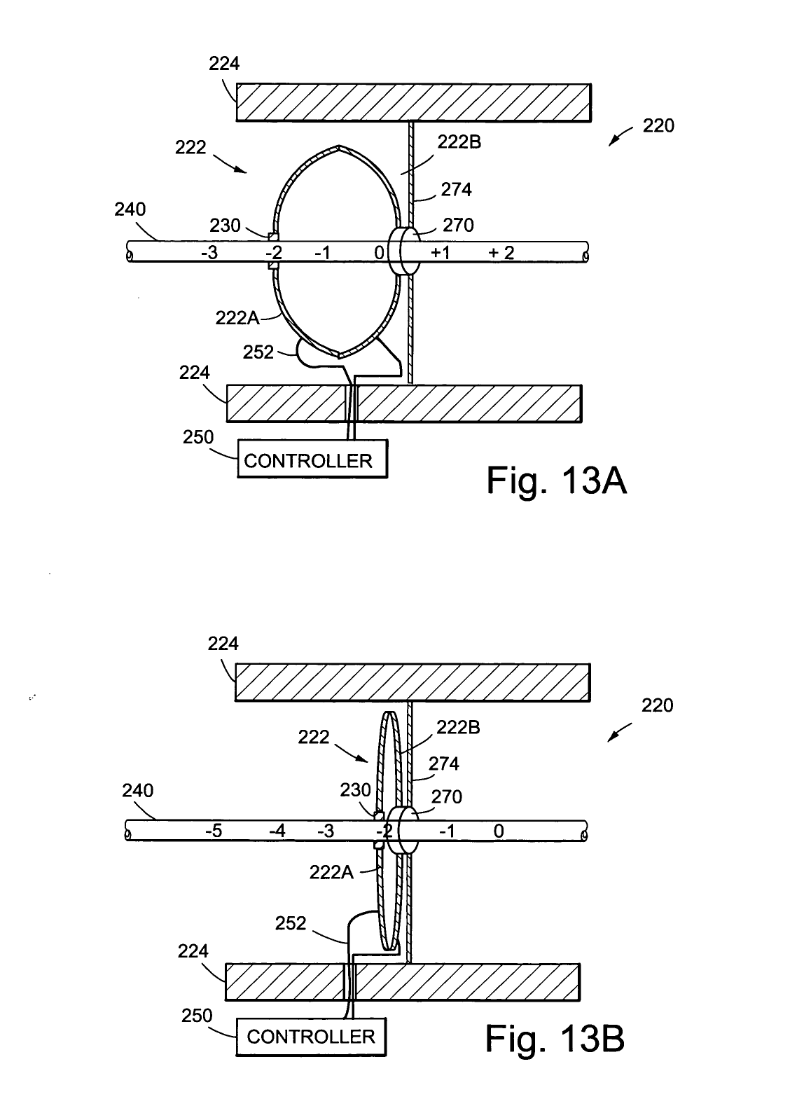

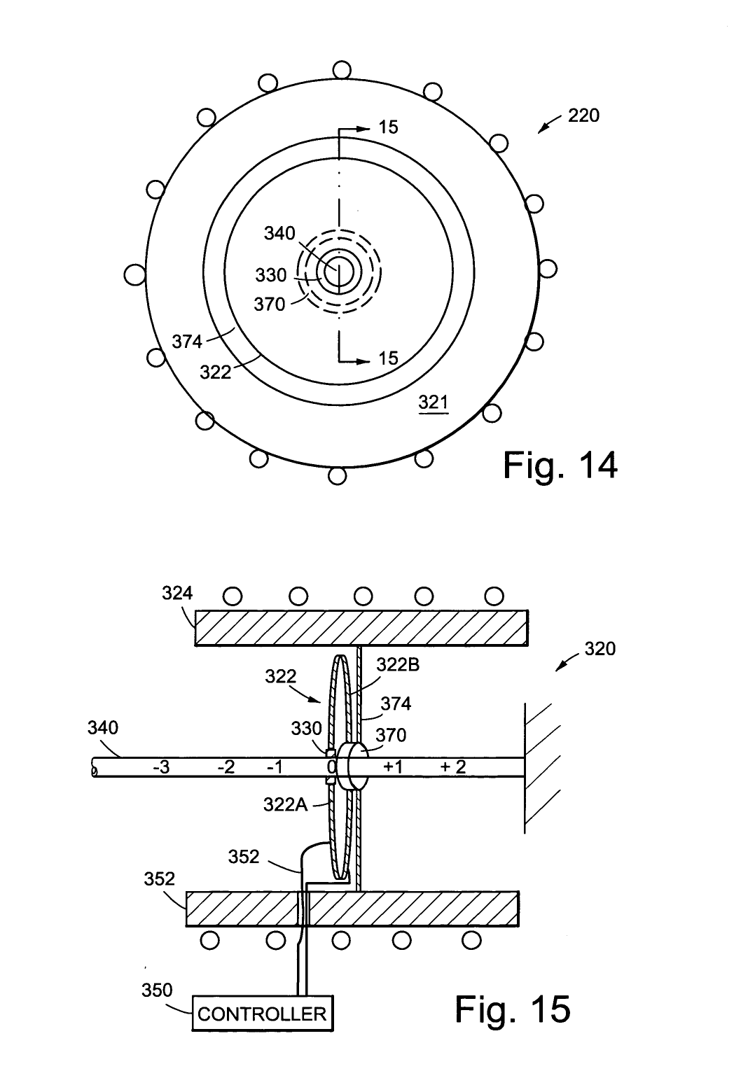

FIG. 14 and FIG. 15 illustrate the fourth example embodiment of an electrically driven actuator, i.e., actuator 320. Actuator 320 comprises a displaceable actuator carriage 321 which includes deformable assembly 322. The deformable assembly 322 has the same bellows type configuration as the deformable assembly 222 of the third embodiment, and thus comprises deformable member 322A and 322B. To depict that carriage 321 is moveable, rollers or bearings are shown about the periphery of carriage 321. It should be understood that such rollers or bearings are merely representative of mobility, and that actual mobility of carriage 321 relative to it environment may be accomplished by alternate arrangements.

Carriage 321 may be a working member or may be connected to, carry, or otherwise linked or associated with a working member to cause displacement or other operation of an actuated device. A coupler 330, shown in FIG. 14 and FIG. 15 as being situated through a hole at the center of deformable member 322A, connects the deformable assembly 322 to a stationary guide element 340. As in the previous embodiments, the coupler 330 is preferably a friction coupler. The stationary guide element 340 can take the form of a shaft or other suitable guideway or track. While guide element 340 is shown in FIG. 15 as being linear, the guide element 340 may be configured to form a non-linear track.

A first of the deformable members, i.e., deformable member 322A, is connected to coupler 330. As in previous embodiments, coupler 330 connects the deformable member 322A to stationary guide element 340. The coupler 330 is preferably formed, fastened, or securely fitted through a hole at the center of deformable member 322A. In the fourth embodiment or mode, guide element 340 is stationary. Preferably the coupler 330 is preferably a friction coupler.

A center of deformable member 322B has an aperture or hole which securely fits over a first axial end of shaft sleeve 370. The shaft sleeve 370 is ringed shaped, fitting concentrically over shaft 340, but having a sufficiently large interior radius so as not to contact shaft 340 (the sleeve 370 thus being free to translate over stationary guide element 340). Whereas the first axial end of shaft sleeve 370 is held in position by deformable member 322B (which itself is held by deformable member 322A and coupler 330), a second axial end of shaft sleeve 370 is held in position by brace(s) 374. The brace(s) 374 extend radially from the circumference of shaft sleeve 370 and are connected to fixed points on carriage 321. The brace(s) 374 hold the shaft sleeve 370 firmly in a fixed position so that shaft sleeve 370 does not travel relative to carriage 321. The brace(s) 374) can take the form of a rigid ring positioned about the second axial end of shaft sleeve 370, or spokes, or even a pair of rigid beams, for example.

FIG. 15 shows the actuator 320 with the deformable member 322A and deformable member 322B being unactivated. When unactivated, the bellows or shell configuration has its flattest (or narrowest) possible configuration, e.g., the deformable member 322A and deformable member 322B have their least degree of curvature. At the time shown in FIG. 14, deformable assembly 322 is essentially aligned with the zero position of stationary guide element 340. For sake of illustrating displacement of carriage 321, the stationary guide element 340 is illustrated as having equally spaced graduation or measurement marks represented by numbers as in previous embodiments.

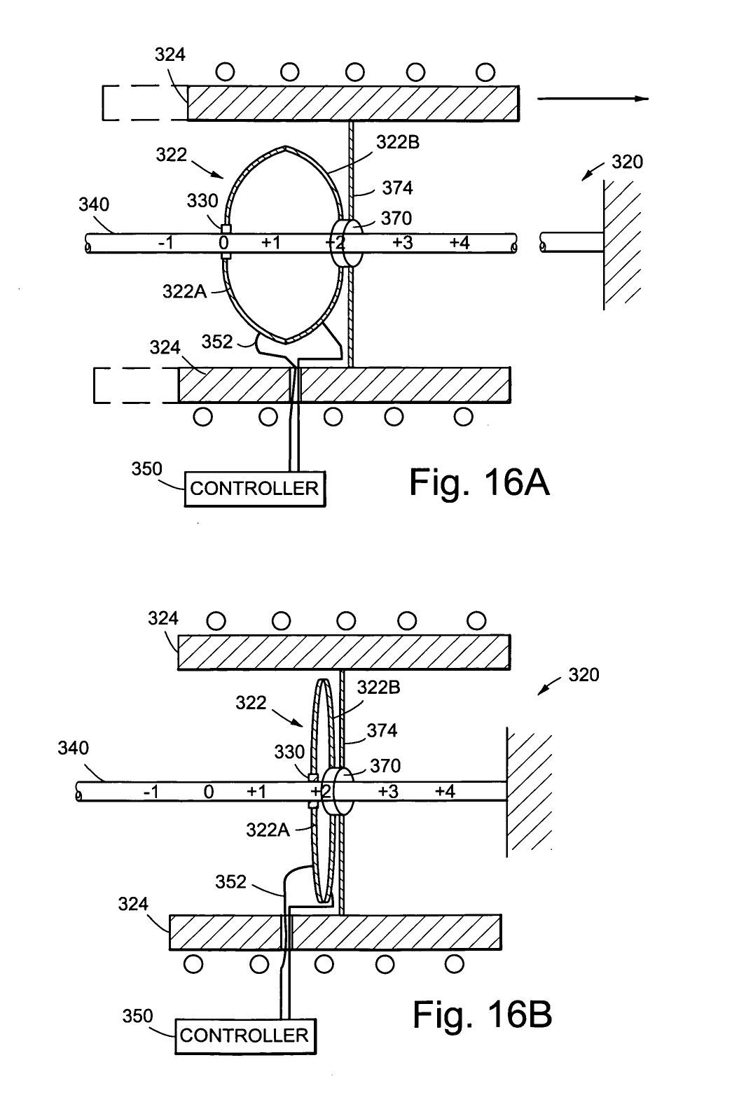

In the embodiment of FIG. 14 and FIG. 15, controller 350 actuates the deformable members 322A and 322B, and particularly deformable member 322A, in a manner to cause coupler 330, as a function of applied voltage, either to engage or slip on guide element 340, and thereby displace the actuator carriage 321 (which carries the deformable assembly 322) relative to the guide element 240. In FIG. 15, as well as FIG. 16A-FIG. 16B, the stationary guide element 340 is shown with reference marks. In the second embodiment, the reference marks of guide element 340 are utilized to depict relative displacement of carriage 321 relative to the center or 0 reference mark of guide element 340.

To the extent not inconsistent herewith, comments concerning the structural and operational details of the preceding embodiments also apply to the fourth embodiment. As a non-limiting example, the actuator 320 also has a controller 350 which supplies a drive signal via line 352 to electrode(s) or other application device(s). Coupler 330 engages the guide element 340 during an engagement portion of a cycle of the drive signal waveform but permits the slip of the coupler 330 relative to guide element 340 during a slip portion of the cycle of the drive signal waveform.

FIG. 16A-FIG. 16B illustrate modes of operation of the embodiment of FIG. 14 and FIG. 15 for displacing the actuator in a first (forward) direction. For the fourth embodiment, the drive signal waveform causes relative displacement of carriage 321 and the deformable assembly 322 carried thereby in a first (or forward) direction when the engagement portion of the drive signal waveform precedes the slip portion of the drive signal waveform.

FIG. 16A shows application of the engagement portion of a first cycle of the drive signal waveform after the time shown in FIG. 15. At this time, both deformable member 322A and deformable member 332B have expanded due to application of the drive signal. During the engagement portion the waveform, the center of deformable member 322A is, via coupler 330, rigidly affixed about guide element 340. Accordingly, the deformation of deformable assembly 322 causes the carriage 321, which is attached to coupler 330 through brace 374, to displace in the forward direction as shown by the solid arrows in FIG. 16A. For example, FIG. 16A shows sleeve 370 to be displaced from about mark 0 to about mark +2 of guide element 140. The deformation of deformable assembly 322 thus causes carriage 321 to displace two units from its former position (and depicted by dotted lines in FIG. 16A) to the new solid line carriage position where sleeve 370 is at mark +2. During the ensuing slip portion of the drive signal waveform shown in FIG. 16B, the coupler 330 slips to near the +2 mark position as deformable assembly 322 regains its relatively flat (inactivated) orientation.

Further forward displacement of carriage 321 in the forward direction is understood with reference to FIG. 8C and FIG. 8D of the second embodiment/mode. Conversely, in the fourth embodiment the drive signal waveform causes relative displacement of carriage 321 and the deformable assembly 322 in a second (or reverse) direction when the slip portion of the drive signal waveform precedes the engagement portion of the drive signal waveform, as understood by analogy with reference to FIG. 9A-FIG. 9D.

In the third and fourth embodiments in which the deformable member is part of an oyster shell or bellows-type deformable assembly, both deformable members of the deformable assembly can take the form of a piezoelectric laminate having multilayers. For example, as previously explained, the piezoelectric laminate can comprise a core of piezoelectric material, with a stainless steel substrate laminated on one side of the piezoelectric core and an aluminum layer laminated on a second side of the core. Generally it is contemplated that the deformable members of the oyster shell embodiments will have the laminates oriented with the stainless steel substrates facing uniformly (e.g., outwardly). However, if the laminated piezoelectric deformable members are arranged with the stainless steel substrate oriented outwardly for one of the deformable members and the stainless steel substrate oriented inwardly for the other deformable member, the deformable assembly will have a temperature compensation or thermal canceling capability as explained in simultaneously-filed U.S. patent application Ser. No. 11,______, entitled “ACTUATORS WITH diaphragm AND METHODS OF OPERATING SAME”, which is incorporated herein by reference in its entirety. In other words, differing orientation of the laminate layers of the deformable members can provide temperature compensation.

It will be understood from the foregoing that, in any of the foregoing embodiments or modes, that the actuator can be driven in either direction (forward or reverse) as many units as desired, and that forward movement may be followed by reverse direction movement, and/or vise versa. Thus, by judiciously forming the drive signal waveform with an appropriate number of cycles having the engagement portion preceding the slip portion, or alternatively the slip portion preceding the engagement portion, and/or any combination of sets of cycles of either type, the actuator can be precisely positioned at a desired location.

In fact, once a gross position (e.g., along shaft 40, shaft 240, or guide element 140) has been reached by “jumping” the shaft with respect to the piezoelectric diaphragm, given the appropriate drive electronics, the shaft can be further micropositioned in small increments (1 micron or less) by simply varying the applied DC bias voltage to the piezoelectric diaphragm. Thus, the apparatus can be utilized to position a load over great lengths with sub-micron accuracy. Micropositioning is not required for most applications, such as positioning an automobile mirror, etc.

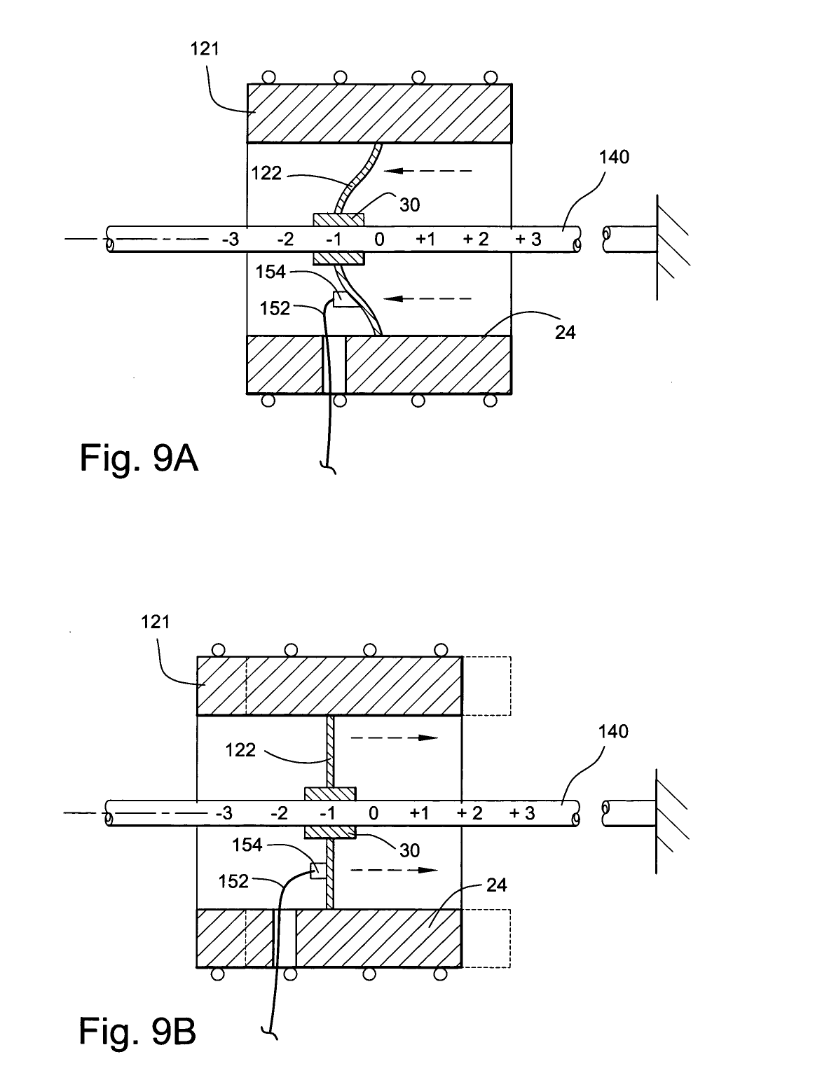

The drive signal waveform can have various shapes such as (for example) a half-sine waveform; a quarter-sine waveform; a sawtooth waveform; or even a hybrid waveform such as a partial quarter-sine, partial sawtooth waveform. Initially it might appear that a simple ramp drive on the return stroke (i.e., the total waveform having a sawtooth wave configuration as shown in FIG. 10C) would be the most appropriate drive signal given that the acceleration during a period of constant velocity would be zero. However, one must take into account the discontinuity that would exist immediately after the “jump” where the shaft would need to be accelerated to the constant velocity. Considering this, it is currently believed that a drive signal waveform with a sine or modified sine return will prove optimum. When the real world characteristics of the piezoelectric diaphragm and electronics are introduced, the system becomes more complex than the voltage equal to position model assumed above. The person skilled in the art understands how to construct and/or modify such a drive signal waveform to take into consideration such factors as impedance, frequency response, drive limitations, etc.

The half-sine waveform used for the return stroke (as described in FIG. 3A and also illustrated in FIG. 10A) yields the most accuracy and repeatability due to the fact that the shaft is brought to a stop between each stroke. However, for maximum performance, a drive signal waveform with a quarter-sine return, such as that shown in FIG. 10B or (more likely) a drive signal waveform having a sawtooth after a quarter sine start (as shown in FIG. 10D) may be the drive signal of choice. Using such a waveform means that, for a given direction, no decelerating forces will be applied. Just prior to the “jump” part of the cycle, instead of being stopped as with the half-sine, the shaft is actually at its maximum velocity with momentum that is opposing the direction of the piezoelectric diaphragm. This allows for greater flexibility in shaft mass and friction coefficient design and ultimately should result in greater actuator force. In addition, the time spent decelerating the shaft in the half-sine mode is eliminated and this directly improves speed. It is entirely conceivable that with proper matching of the drive waveform to the shaft speed on a dynamic basis, that the shaft can be accelerated to very high speeds (much as a child standing on the ground continually accelerates a merry-go-round by grabbing and pulling, grabbing and pulling, etc). Such an actuator could be further enhanced by using a friction coupler that has a high coefficient of static friction and a low coefficient of dynamic friction. Smoothly, nearly step-free motion could be achieved. Various other possibilities are obtained by mixing and matching shaft momentum and diaphragm speed and acceleration.

Other embodiments can have differing elements than those illustrated. For example, in some embodiments the shaft can be replaced with a tensioned string or belt. Moreover, for a given load, suitable open loop positioning (a la stepper motor) is achieveable with a friction element/shaft arrangement. To increase the open loop accuracy, a detented shaft/friction element can be utilized for more accurate registration.

The electrically driven mechanical actuators described herein convert short axial movements from a displacement device such as a piezoelectric diaphragm, piezoelectric polymer, voice coil, etc. into longer axial movements that can be extremely long, are reversible, can be extremely accurate (to a microscopic scale), can present a force that approaches the instantaneous force of the short stroke device, and can move at speeds up to several inches per second or more.

The electrically driven mechanical actuators encompassed hereby can be utilized in myriad environments and applications. As mentioned above, shaft 40 of the first embodiment or the shaft 240 of the third embodiment may be a working member or may be connected to or otherwise linked or associated with a working member to cause displacement or other operation of an actuated device. Similarly, carriage 121 of the second embodiment may be a working member or may be connected to, carry, or otherwise linked or associated with a working member to cause displacement or other operation of an actuated device. Examples of actuated devices operated or displaceable by shaft 40, shaft 240, or carriage 121 include the following (which are supplied only as a partial, non-exhaustive, representative list to depict the wide range of environments and applications): robotics, automotive (e.g., accessories such as mirrors), printers, print heads, valves, valve actuators, fax machines, scanners, photocopiers, positioning apparatus for manufacturing processes (e.g., for optical steppers), moving toys, etc.

In an example implementation, the deformable member 22 and diaphragm 122 preferably comprises a multi-layered laminate. The multi-layered laminate can comprise a piezoelectric wafer which is laminated by an adhesive between a metallic substrate layer and an outer metal layer. The structure of the multi-layered laminate and a process for fabricating the same are described in one or more of the following (all of which are incorporated herein by reference in their entirety): PCT Patent Application PCT/US01/28947, filed 14 Sep. 2001; U.S. patent application Ser. No. 10/380,547, filed Mar. 17, 2003, entitled “Piezoelectric Actuator and Pump Using Same”; U.S. patent application Ser. No. 10/380,589, filed Mar. 17, 2003, entitled “Piezoelectric Actuator and Pump Using Same”, and simultaneously filed United States Provisional Patent Application (attorney docket: 4209-72), entitled “PIEZOELECTRIC DIAPHRAGM ASSEMBLY WITH CONDUCTORS ON FLEXIBLE FILM”.

While in the illustrated implementations a piezoelectric diaphragm is utilized for the deformable member 22, diaphragm 122, deformable members 222A and 222B, it will be understood that deformable member 22 and diaphragm 122 can take other forms. For example, a piezoelectric polymer or a voice coil can instead be utilized for deformable member 22 or diaphragm 122. Other alternatives include muscle wire or elements deformable by expansion.

The materials and relative positioning of coupler 30 and shaft 40/guide element 140 should be such that, depending on the activation of deformable member 22 or diaphragm 122, coupler 30 can selectively engage shaft 40/guide element 140 or allow slippage between coupler 30 and shaft 40/guide element 140, as above explained. In the illustrated implementations the coupler 30 can be a brass tube which has a friction fit over shaft 40/guide element 140. The shaft 40 and/or guide element 140 can be of any suitable material forming a friction fit with coupler 30, such as a solid plastic rod, for example. Other materials suitable for forming a jump-prone connection include nylon nuts and spring-loaded plastic.

In shaping the drive signal waveform and operating the actuator 20 generally, the controllers 50 and 150 can assume various forms. In this regard, the individual function block shown in FIG. 2 for controller 50 and in FIG. 7 for controller 150 may be implemented using individual hardware circuits, using software functioning in conjunction with a suitably programmed digital microprocessor or general purpose computer, using an application specific integrated circuit (ASIC), and/or using one or more digital signal processors (DSPs). Moreover, the functionality of controller 50 and controller 150 can reside in a single unit, or be distributed among several co-located or physically separated units if desired.

In other embodiments, multiple piezoelectric diaphragms and friction drives are provided in “stacked” arrangements for increased drive torque. In the simplest form, a stack of piezoelectric elements, each with a separate friction drive, all work in unison to move a shaft with greater force. Basically, the forces add. Slightly more complex arrangements involve driving the piezoelectric members sequentially in various ways so as to increase force at the expense of speed.

As an example of the foregoing, a 2-piezoelectric element drive might involve one piezoelectric member holding its position while the other is re-positioned. Then the new re-positioned piezoelectric member holds that position while the first is then re-postioned and so on. Thus, the shaft is always being “held” by at least one piezoelectric member and stronger friction fittings may be employed, resulting in both more active torque and more static torque.

As another example, a 3-piezo drive might involve 2 piezoelectric elements holding position while one is re-positioned, followed by the second piezoelectric member and then the third piezoelectric member, etc., using a technique similar to “inch worm” driving. With such a 3-piezo drive, the “jumping” wave drive is not absolutely necessary because the shaft is always being held by two piezoelectric member with only one piezoelectric member trying to “slip”. The “jumping” waveform will, however, generate greater torque than the non-jumping drive because higher friction in the nuts can be employed.

In yet other embodiments, friction nuts in either single or multiple piezo drives are “active”. By “active” is meant that the friction is electrically controlled so that they can actively “grab” or “release” the shaft on command from the controller. A block or chunk of piezo material that expands and contracts under electrical control serves to “grab” and “release”. Such arrangement provides for a very powerful and reliable motor.

Although various embodiments have been shown and described in detail, the claims are not limited to any particular embodiment or example. None of the above description should be read as implying that any particular element, step, range, or function is essential such that it must be included in the claims scope. The scope of patented subject matter is defined only by the claims. The extent of legal protection is defined by the words recited in the allowed claims and their equivalents. It is to be understood that the invention is not to be limited to the disclosed embodiment, but on the contrary, is intended to cover various modifications and equivalent arrangements.

What is claimed is:

1. An electrically driven actuator comprising:
a deformable member which deforms as a function of applied voltage;
a shaft;
a coupler which connects the deformable member to the shaft;
a controller which actuates the deformable member by applying voltage in a manner to cause the coupler, as a function of applied voltage, either to engage or slip relative to the shaft and thereby cause relative displacement of the shaft and the deformable member.

2. The apparatus of claim 1, wherein the deformable member is a piezoelectric diaphragm, a piezoelectric polymer, or a voice coil.

3. The apparatus of claim 1, wherein the controller actuates the deformable member to cause linear relative displacement of the shaft and the deformable member.

4. The apparatus of claim 1, wherein the coupler engages the shaft during an engagement portion of a cycle of a drive signal waveform applied to the deformable member and permits the slip of the coupler during a slip portion of the cycle of the drive signal waveform.

5. The apparatus of claim 4, wherein the drive signal waveform causes relative displacement of the shaft and the deformable member in a first direction when the slip portion of the drive signal waveform precedes the engagement portion of the drive signal waveform, and wherein the drive signal waveform causes relative displacement of the deformable member and the shaft in a second direction opposite to the first direction when the slip portion of the drive signal waveform follows the engagement portion of the drive signal waveform.

6. The apparatus of claim 4, wherein the drive signal waveform is one of a half-sine waveform, a quarter-sine waveform, a sawtooth waveform; and a partial quarter-sine/partial sawtooth waveform.

7. The apparatus of claim 1, wherein the coupler is a friction coupler.

8. The apparatus of claim 1, wherein the deformable member is a first deformable member of an assembly, the assembly comprising the first deformable member and a second deformable member, the first deformable member and the second deformable member being essentially circular shaped elements which are connected at their peripheries, a center of the first deformable member engaging the coupler, wherein the actuator further comprises:
a sleeve which accommodates relative motion of the shaft and the sleeve, the second deformable member being connected to the sleeve.

9. The apparatus of claim 8, wherein a center of the second deformable member engages the sleeve.

10. The apparatus of claim 8, wherein the shaft is translatable and the sleeve is stationary.

11. The apparatus of claim 8, wherein the sleeve is translatable and the shaft is stationary.

12. A method of operating an actuator comprising:
connecting a shaft to a deformable member with a coupler, the deformable member being deformable as a function of voltage applied in a drive signal;
driving the deformable member with the drive signal in a manner to cause the coupler, as a function of applied voltage, either to engage or slip on the shaft and thereby cause relative displacement of the deformable member and the shaft.

13. The method of claim 12, further comprising configuring the drive signal so that the coupler engages the shaft during an engagement portion of a cycle of a drive signal waveform and permits the slip of the coupler during a slip portion of the cycle of the drive signal waveform.

14. The method of claim 13, further comprising:
configuring the drive signal to cause relative displacement of the shaft and the deformable member in a first direction when the slip portion of the drive signal waveform precedes the engagement portion of the drive signal waveform; and,
configuring the drive signal waveform to cause the relative displacement of the deformable member and the shaft in a second direction opposite to the first direction when the slip portion of the drive signal waveform follows the engagement portion of the drive signal waveform.

15. The method of claim 13, further comprising applying the drive signal waveform as one of a half-sine waveform, a quarter-sine waveform, a sawtooth waveform; and a partial quarter-sine/partial sawtooth waveform.

16. An electrically driven actuator comprising:
a piezoelectric diaphragm;
a displaceable actuator element;
a coupler which connects the piezoelectric diaphragm to the actuator element;
a controller which actuates the piezoelectric diaphragm in a manner to cause the coupler, as a function of applied voltage, either to engage or slip on the actuator element and thereby displace the actuator element relative to the piezoelectric diaphragm.

17. The apparatus of claim 16, wherein the actuator element is a shaft having an axis, and wherein the controller actuates the piezoelectric diaphragm to displace linearly the actuator element along the axis.

18. The apparatus of claim 16, wherein the coupler engages the actuator element during an engagement portion of a cycle of a waveform of a drive signal applied to the piezoelectric diaphragm and permits the slip of the coupler during a slip portion of the cycle of the waveform.

19. The apparatus of claim 18, wherein the drive signal waveform causes the actuator element to displace in a first direction when the slip portion of the drive signal waveform precedes the engagement portion of the drive signal waveform; and wherein the drive signal waveform causes the actuator element to displace in a second direction opposite to the first direction when the slip portion of the drive signal waveform follows the engagement portion of the drive signal waveform.

20. The apparatus of claim 18, wherein the drive signal waveform is one of a half-sine waveform, a quarter-sine waveform, a sawtooth waveform; and a partial quarter-sine/partial sawtooth waveform.

21. The apparatus of claim 16, wherein the coupler is a friction coupler.

22. An electrically driven actuator comprising:
a displaceable actuator which includes a piezoelectric diaphragm;
a guide element;
a coupler which connects the piezoelectric diaphragm to the guide element;
a controller which actuates the piezoelectric diaphragm in a manner to cause the coupler, as a function of applied voltage, either to engage or slip on the guide element and thereby displace the actuator relative to the guide element.

23. The apparatus of claim 22, wherein the guide element is a stationary shaft having an axis, and wherein the controller actuates the piezoelectric diaphragm to displace linearly the actuator along the axis.

24. The apparatus of claim 22, wherein the coupler engages the guide element during an engagement portion of a cycle of a waveform of a drive signal applied to the piezoelectric diaphragm and permits the slip of the coupler during a slip portion of the cycle of the waveform.

25. The apparatus of claim 24, wherein the drive signal waveform causes the actuator element to displace in a first direction when the slip portion of the drive signal waveform precedes the engagement portion of the drive signal waveform; and wherein the drive signal waveform causes the actuator element to displace in a second direction opposite to the first direction when the slip portion of the drive signal waveform follows the engagement portion of the drive signal waveform.

26. The apparatus of claim 24, wherein the drive signal waveform is one of a half-sine waveform, a quarter-sine waveform, a sawtooth waveform; and a partial quarter-sine/partial sawtooth waveform.

27. The apparatus of claim 22, wherein the coupler is a friction coupler.

28. An electrically driven actuator comprising:
a deformable assembly, the assembly comprising a first deformable member and a second deformable member, the first deformable member and the second deformable member being deformable as a function of applied voltage, the first deformable member and the second deformable member being essentially circular shaped elements which are connected at their peripheries;
a shaft;
a coupler which connects the first deformable member to the shaft;
a sleeve for fitting over the shaft and accommodating relative motion of the shaft and the sleeve, the second deformable member being connected to the sleeve;
a controller which actuates the first deformable member and the second deformable member by applying voltage in a manner to cause the coupler, as a function of applied voltage, either to engage or slip relative to the shaft and thereby cause relative displacement of the shaft and the first deformable member.

29. The apparatus of claim 28, wherein the shaft is translatable and the sleeve is stationary.

30. The apparatus of claim 28, wherein the sleeve is translatable and the shaft is stationary.

31. The apparatus of claim 28, wherein a center of the second deformable member engages the sleeve.

32. The apparatus of claim 28, wherein the first deformable member and the second deformable member are piezoelectric diaphragms.
